(19) United States
(12) Patent Application Publication
(10) Pub. No.: US 2024/0074148 A1
(43) Pub. Date: Feb. 29, 2024

(54) SEMICONDUCTOR DEVICE

(71) Applicant: Samsung Electronics Co., Ltd., Suwon-si (KR)

(72) Inventors: Seunghee Lee, Suwon-si (KR); Yurim Kim, Suwon-si (KR); Teawon Kim, Suwon-si (KR); Yongsuk Tak, Suwon-si (KR)

(21) Appl. No.: 18/230,916

(22) Filed: Aug. 7, 2023

(30) Foreign Application Priority Data
Aug. 24, 2022 (KR) 10-2022-0106346

(51) Int. Cl. H10B 12/00

(52) U.S. Cl. CPC H10B 12/315; H10B 12/05; H10B 12/50

(57) ABSTRACT

A semiconductor device includes a plurality of bit lines arranged on a substrate and extending in a first horizontal direction, a mold insulating layer arranged on the bit lines and including a plurality of openings extending in a second horizontal direction, respectively, a plurality of channel layers respectively arranged on the bit lines and including a first vertical extension portion, in each opening of the mold insulating layer, a plurality of passivation layers respectively arranged on each vertical extension portion, a gate insulating layer arranged to face each vertical extension portion with each passivation layer therebetween, and a plurality of word lines extending in the second horizontal direction on the gate insulating layer and including first word lines respectively arranged on a first sidewall of each opening of the mold insulating layer and second word lines respectively arranged on a second sidewall of each opening of the mold insulating layer.

### CROSS-REFERENCE TO RELATED APPLICATION(S)

This application is based on and claims priority under 35 U.S.C. § 119 to Korean Patent Application No. 10-2022-0106346, filed on Aug. 24, 2022, in the Korean Intellectual Property Office, the disclosure of which is incorporated by reference herein in its entirety.

### BACKGROUND

The inventive concepts relate to a semiconductor device, and more particularly, to a semiconductor device including a vertical channel transistor.

The size of a dynamic random access memory (DRAM) device is also being reduced according to downscaling of a semiconductor device. In a DRAM device having a 1-transistor-1-capacitor (1T-1C) structure in which one capacitor is connected to one transistor, there is a problem that a leakage current through a channel region gradually increases as a device is miniaturized. In order to reduce the leakage current, a transistor using an oxide semiconductor material as a channel layer has been proposed.

### SUMMARY

The inventive concepts provide a semiconductor device capable of having reduced leakage current and excellent electrical characteristics.

According to an aspect of the inventive concept, there is provided a semiconductor device including a plurality of bit lines arranged on a substrate and extending in a first horizontal direction, a mold insulating layer arranged on the plurality of bit lines and including a plurality of openings extending in a second horizontal direction, respectively, a plurality of channel layers respectively arranged on the plurality of bit lines and including a first vertical extension portion, in each opening of the mold insulating layer, a plurality of passivation layers respectively arranged on each first vertical extension portion, a gate insulating layer arranged to face each vertical extension portion with each passivation layer therebetween, and a plurality of word lines extending in the second horizontal direction on the gate insulating layer and including first word lines respectively arranged on a first sidewall of each opening of the mold insulating layer and second word lines respectively arranged on a second sidewall of each opening of the mold insulating layer.

According to another aspect of the inventive concept, there is provided a semiconductor device including a plurality of bit lines arranged on a substrate and extending in a first horizontal direction, a mold insulating layer arranged on the plurality of bit lines and including a plurality of openings extending in a second horizontal direction, respectively, a plurality of channel layers respectively arranged on the plurality of bit lines and including a vertical extension portion and a horizontal extension portion, in each opening of the mold insulating layer, a plurality of passivation layers respectively arranged on each vertical extension portion and each horizontal extension portion, and including an oxide, a gate insulating layer arranged to face each vertical extension portion and each horizontal extension portion with each passivation layer therebetween, and a plurality of word lines extending in the second horizontal direction on the gate insulating layer.

According to another aspect of the inventive concept, there is provided a semiconductor device including a peripheral circuit arranged on a substrate, a plurality of bit lines arranged on the peripheral circuit and extending in a first horizontal direction, a shield structure extending in the first horizontal direction between the plurality of bit lines, a mold insulating layer arranged on the plurality of bit lines and the shield structure and including a plurality of openings extending in a second horizontal direction, respectively, a plurality of channel layers arranged on the plurality of bit lines, respectively, and including vertical and horizontal extension portion, in each opening of the mold insulating layer, a plurality of passivation layers respectively arranged on each vertical extension portion and each horizontal extension portion, and including an oxide, a gate insulating layer arranged to face each vertical extension portion and each horizontal extension portion with each passivation layer therebetween, a plurality of word lines extending in the second horizontal direction on the gate insulating layer, a landing pad formed on each channel layer, and a capacitor structure arranged on the landing pad.

### BRIEF DESCRIPTION OF THE DRAWINGS

Embodiments of the inventive concept will be more clearly understood from the following detailed description taken in conjunction with the accompanying drawings in which:

FIG. 1 is a layout diagram illustrating a semiconductor device according to example embodiments;

FIG. 2 is an enlarged layout diagram of a part of FIG. 1 according to example embodiments;

FIG. 3 illustrates cross-sectional views taken along lines A-A′ and B-B′ of FIG. 2 according to example embodiments;

FIG. 4 illustrates cross-sectional views taken along lines C-C′, D-D′ and E-E′ of FIG. 2 according to example embodiments;

FIG. 5 is an enlarged cross-sectional view of a part CX1 of FIG. 3 according to example embodiments;

FIG. 6 is a cross-sectional view illustrating a semiconductor device according to example embodiments;

FIG. 7 is a cross-sectional view illustrating a semiconductor device according to example embodiments;

FIG. 8 is a cross-sectional view illustrating a semiconductor device according to example embodiments;

FIGS. 9A to 15A, 9B to 15B, and 9C to 15C are schematic diagrams illustrating a method of manufacturing a semiconductor device according to example embodiments; FIGS. 9A, 10A, 11A, 12A, 13A, 14A, and 15A are plan views of semiconductor devices schematically shown according to process order; FIGS. 9B, 10B, 11B, 12B, 13B, 14B, and 15B are cross-sectional views taken along lines A-A′ and B-B′ of FIG. 9A; and FIGS. 9C, 10C, 11C, 12C, 13C, 14C, and 15C are cross-sectional views taken along lines C-C′, D-D′, and E-E′ of FIG. 9A.

### DETAILED DESCRIPTION OF THE EMBODIMENTS

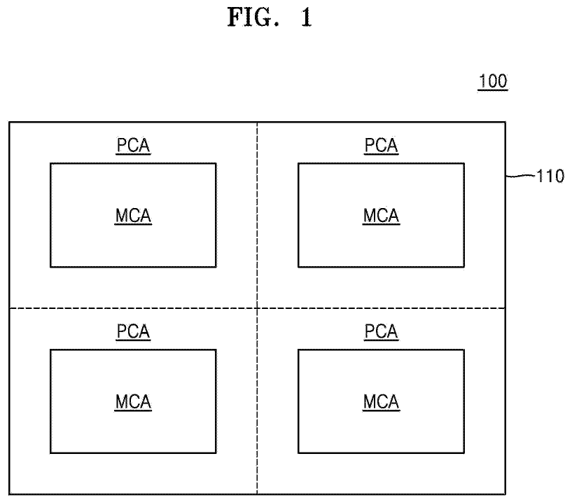

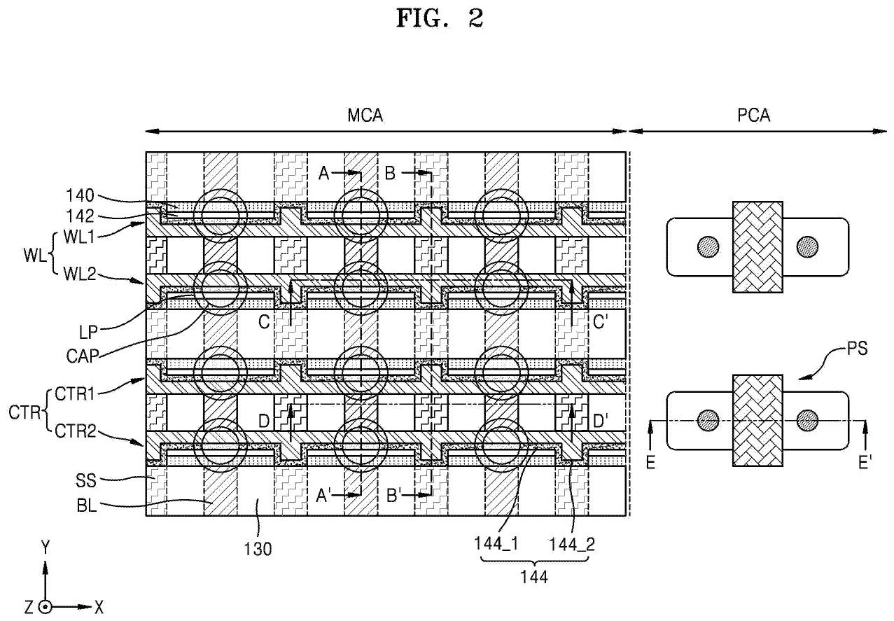

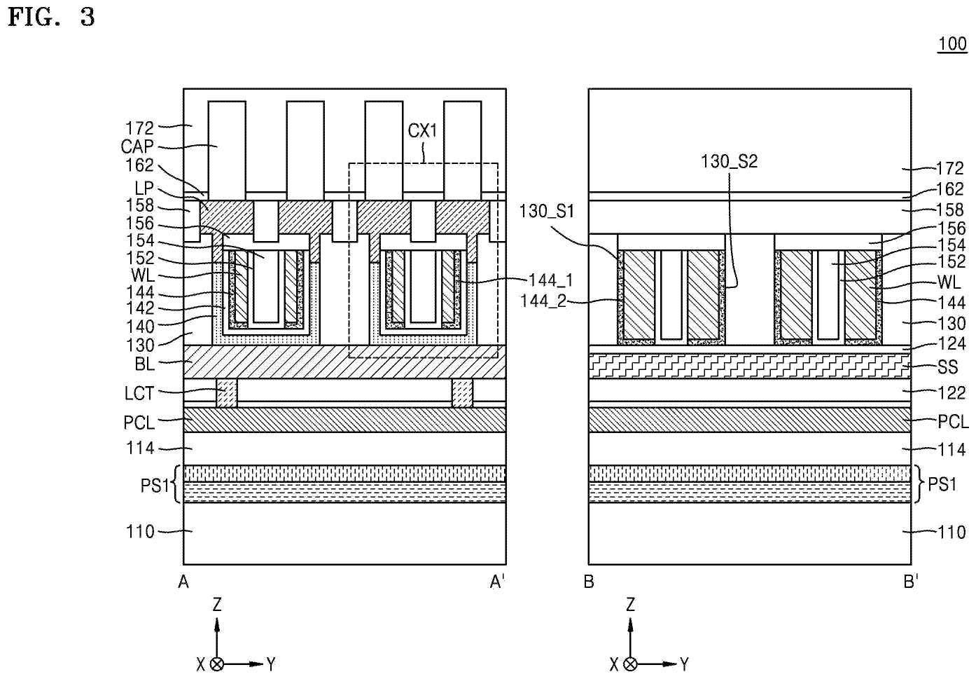

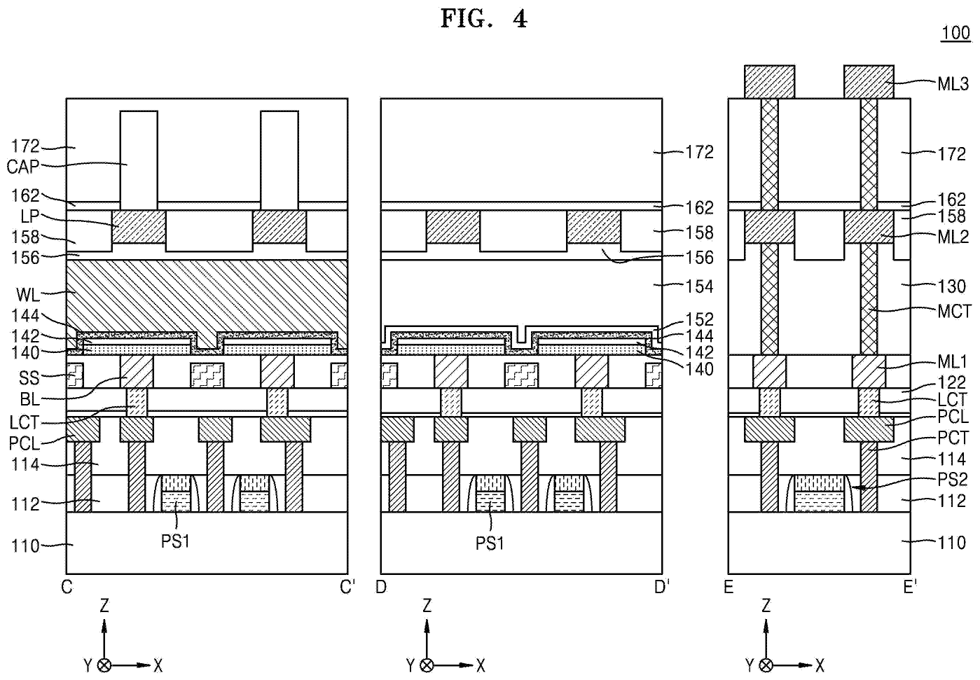

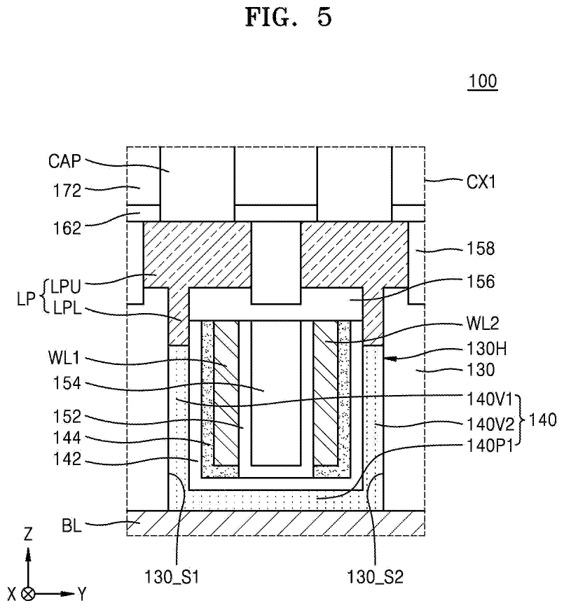

FIG. 1 is a layout diagram illustrating a semiconductor device 100 according to example embodiments. FIG. 2 is an enlarged layout diagram of a part of FIG. 1 according to example embodiments. FIG. 3 illustrates cross-sectional views taken along lines A-A′ and B-B′ of FIG. 2 according to example embodiments. FIG. 4 illustrates cross-sectional views taken along lines C-C′, D-D′ and E-E′ of FIG. 2. FIG. 5 is an enlarged cross-sectional view of a part CX1 of FIG. 3 according to example embodiments.

Referring to FIGS. 1 to 5, a semiconductor device 100 may include a substrate 110 including cell array areas MCAs and peripheral circuit areas PCAs. In some embodiments, each of the cell array areas MCAs may be a memory cell region of a dynamic random access memory (DRAM) device, and each of the peripheral circuit areas PCAs may be a core area or a peripheral circuit area of the DRAM device. For example, the peripheral circuit area PCA may include a peripheral circuit transistor (not shown) for transmitting signals and/or power to a memory cell array included in the cell array area MCA. In some embodiments, the peripheral circuit transistor (not shown) may constitute various circuits such as a command decoder, a control logic circuit, an address buffer, a row decoder, a column decoder, a sense amplifier, and a data input/output circuit.

As shown in FIG. 2, a plurality of word lines WL extending in a first horizontal direction X and a plurality of bit lines BL extending in a second horizontal direction Y may be arranged on the cell array area MCA of the substrate 110. A plurality of cell transistors CTR may be arranged at intersections of the plurality of word lines WL and the plurality of bit lines BL. A plurality of capacitor structures CAPs may be arranged on the plurality of cell transistors CTR, respectively.

The plurality of word lines WL may include first word lines WL1 and second word lines WL2 alternately arranged in the second horizontal direction Y, and the plurality of cell transistors CTR may include first cell transistors CTR1 and second cell transistors CTR2 alternately arranged in the second horizontal direction Y. Each of the first cell transistors CTR1 may be arranged on each of the first word lines WL1, and each of the second cell transistors CTR2 may be arranged on each of the second word lines WL2.

The first cell transistor CTR1 and the second cell transistor CTR2 may have a mirror symmetrical structure with respect to each other. For example, the first cell transistor CTR1 and the second cell transistor CTR2 may have a mirror symmetrical structure with respect to the center line between the first cell transistor CTR1 and the second cell transistor CTR2 extending in the first horizontal direction X.

In some embodiments, a width of each of the plurality of word lines WL may be 1F, a pitch (i.e., the sum of the width and interval) of each of the plurality of word lines WL may be 2F, a width of each of the plurality of bit lines BL may be 1F, a pitch (i.e., the sum of the width and interval) of each of the plurality of bit lines BL may be 2F, and the unit area for forming one cell transistor CTR may be 4F². Therefore, since the cell transistor CTR may have a cross point type in which a relatively small unit area is required, it may be advantageous to improve the degree of integration of the semiconductor device 100.

As illustrated in FIG. 3, a peripheral circuit structure PS (of FIG. 2) may be arranged on the substrate 110 in the cell array area MCA and the peripheral circuit area PCA, and the plurality of cell transistors CTR (of FIG. 2) and the plurality of capacitor structures CAP may be arranged on the peripheral circuit structure PS in the cell array area MCA.

The substrate 110 may include or be formed of silicon, for example, single crystalline silicon, polycrystalline silicon, or amorphous silicon. In some embodiments, the substrate 110 may include or be formed of at least one selected from Ge, SiGe, SiC, GaAs, InAs, and InP. In some embodiments, the substrate 110 may include a conductive region, such as an impurity-doped well, or an impurity-doped structure.

The peripheral circuit structure PS (of FIG. 2) may include core circuits PS1 and peripheral circuits PS2 (of FIG. 4). For example, the core circuits PS1 may include a sense amplifier arranged in the cell array area MCA, and the peripheral circuits PS2 (of FIG. 4) may include a word line driver and/or control logic circuit arranged in the peripheral circuit area PCA. The peripheral circuit structure PS may include an NMOS transistor and a PMOS transistor formed on the substrate 110, and may be electrically connected to a bit line BL or a word line WL through, for example, a peripheral circuit wiring PCL and a peripheral circuit contact PCT.

A lower insulating layer 112 may cover the sidewall of the peripheral circuit structure PS on the substrate 110, and a peripheral circuit insulating layer 114 may cover the top surface of the peripheral circuit structure PS and the sidewall of the peripheral circuit wiring PCL on the lower insulating layer 112. Each of the lower insulating layer 112 and the peripheral circuit insulating layer 114 may include or be formed of an oxide film, a nitride film, a low-k dielectric film, or a combination thereof, and may be formed in a stacked structure of a plurality of insulating layers.

The bit line BL extending in the second horizontal direction Y may be arranged on the peripheral circuit insulating layer 114. In some embodiments, the bit line BL may include or be formed of Ti, TiN, Ta, TaN, Mo, Ru, W, WN, Co, Ni, TiSi, TiSiN, WSi, WSiN, TaSiN, RuTiN, CoSi, NiSi, polysilicon, or a combination thereof. The bit line BL may be connected to the peripheral circuit wiring PCL through line contact plugs LCT.

As shown in FIG. 4, a lower wiring line ML1 may be arranged at the same level as the bit line BL in the peripheral circuit area PCA. The lower wiring line ML1 may be connected to the peripheral circuits PS2 through the line contact plugs LCT, and may include the same material as the material constituting the bit line BL.

A first insulating layer 122 surrounding the line contact plugs LCT may be arranged between the bit line BL and the peripheral circuit wiring PCL and between the lower wiring line ML1 and the peripheral circuit wiring PCL, and a second insulating layer 124 may be arranged between the plurality of bit lines BL. The first insulating layer 122 and the second insulating layer 124 may include or be formed of an oxide layer, a nitride layer, a low-k dielectric layer, or a combination thereof.

A shield structure SS may extend between the plurality of bit lines BL in the second horizontal direction Y. The shield structure SS may include or be formed of a conductive material such as tungsten, aluminum, or copper, may be surrounded by the second insulating layer 124, and an upper surface of the shield structure SS may be arranged at a level lower than an upper surface of the plurality of bit lines BL. In some embodiments, the shield structure SS may be formed of a conductive material and may include an air gap or void therein, or in some other embodiments, air gaps may be defined or formed in the second insulating layer 124 instead of the shield structure SS.

A mold insulating layer 130 may be arranged on the bit line BL and the second insulating layer 124. The mold insulating layer 130 may include a plurality of openings 130H (of FIG. 5). Each of the plurality of openings 130H may extend in the first horizontal direction X, and the upper surface of the bit line BL may be exposed to the bottom of each of the plurality of openings 130H. Each of the plurality of openings 130H may include a first sidewall 130_S1 and a second sidewall 130_S2 spaced apart from each other in the second horizontal direction Y, and the first sidewall 130_S1 and the second sidewall 130_S2 may extend in parallel to each other in the first horizontal direction X. The mold insulating layer 130 may include or be formed of an oxide layer, a nitride layer, a low-k dielectric layer, or a combination thereof.

A plurality of channel layers 140 may be arranged on an inner wall of each of the plurality of openings 130H. The channel layer 140 of the first cell transistor CTR1 may be arranged on the first sidewall 130_S1 and the bottom of each of the plurality of openings 130H, and the channel layer 140 of the second cell transistor CTR2 may be arranged on the second sidewall 130_S2 and the bottom of each of the plurality of openings 130H. The channel layer 140 of the first cell transistor CTR1 and the channel layer 140 of the second cell transistor CTR2 may have mirror symmetrical shapes with respect to each other.

Each of the plurality of channel layers 140 may include a first vertical extension portion 140V1, a second vertical extension portion 140V2, and a horizontal extension portion 140P1. For example, the first vertical extension portion 140V1 of the channel layer 140 may extend vertically on the first sidewall 130_S1 of each of the plurality of openings 130H, the second vertical extension portion 140V2 may extend vertically on the second sidewall 130_S2 of each of the plurality of openings 130H, and the horizontal extension portion 140P1 may be connected to bottom surfaces of the first and second vertical extension portions 140V1 and 140V2. For example, the horizontal extension portion 140P1 may be arranged on a bottom surface of each of the plurality of openings 130H. For example, each of the plurality of channel layers 140 may have a U-shaped vertical cross-section.

A part of the first vertical extension portion 140V1 and the horizontal extension portion 140P1 of one channel layer 140 may function as a channel region of the first cell transistor CTR1, and a part of the second vertical extension portion 140V2 and the horizontal extension portion 140P1 of one channel layer 140 may function as a channel region of the second cell transistor CTR2. A part of the horizontal extension portion 140P1 may contact the upper surface of the bit line BL and may function as a contact region shared by the first cell transistor CTR1 and the second cell transistor CTR2.

In some embodiments, each of the plurality of channel layers 140 may include or be formed of an oxide semiconductor material. For example, each of the plurality of channel layers 140 may include a material having a band gap larger than that of polysilicon, for example, a material having a band gap larger than 1.65 eV. In some embodiments, each of the plurality of channel layers 140 includes or be formed of at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), and zirconium zinc tin oxide (ZrₓZn_{y}Sn_{z}O). In some other embodiments, each of the plurality of channel layers 140 may include or be formed of a two-dimensional semiconductor material, and the two-dimensional semiconductor material may include graphene, carbon nanotubes, or a combination thereof.

A passivation layer 142 may be arranged on an inner wall of each of the plurality of channel layers 140. For example, the passivation layer 142 may be conformally arranged on the sidewall of the first vertical extension portion 140V1, the sidewall of the second vertical extension portion 140V2, and the upper surface of the horizontal extension portion 140P1 of each of the plurality of channel layers 140. In some embodiments, the passivation layer 142 may include or be formed of oxide, for example, at least one of hafnium oxide (HfO₂), silicon oxide (Sift), aluminum oxide (Al₂O₃), zirconium oxide (ZrO₂), lanthanum oxide (La₂O₃), magnesium oxide (MgOₓ), boron oxide (B₂O₃), and titanium oxide (TiO₂). In some embodiments, the passivation layer 142 may include nitride or oxynitride, for example, at least one of aluminum nitride (AlN), aluminum oxynitride (AlON), silicon nitride (SiN), and silicon oxynitride (SiON). The passivation layer 142 may be arranged to entirely cover the inner wall and upper surface of the channel layer 140, and may prevent damage to the surface of the channel layer 140 during a patterning process of the channel layer 140. The passivation layer 142 may not be in contact with the mold insulating layer 130. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

A gate insulating layer 144 may be arranged on an inner wall of each of the plurality of channel layers 140. For example, the gate insulating layer 144 may be arranged to face the first and second vertical extension portions 140V1 and 140V2 and the horizontal extension portion 140P1 of the channel layer 140 with the passivation layer 142 therebetween.

In some embodiments, the gate insulating layer 144 may be formed of at least one selected from a high-k dielectric material and a ferroelectric material having a dielectric constant higher than that of silicon oxide. In some embodiments, the gate insulating layer 144 may be formed of at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead titanate zirconate (PbZrTiO), tantalate strontium bismuth (SrTaBiO), bismuth iron oxide (BiFeO), strontium titanium oxide (SrTiO), yttrium oxide (YO), aluminum oxide (AlO), and lead scandium tantalum oxide (PbScTaO).

The gate insulating layer 144 may include a first part 144_1 arranged on a sidewall of the passivation layer 142 and not in contact with the first sidewall 130_S1 of the opening 130H of the mold insulating layer 130 and a second part 144_2 in contact with the first sidewall 130_S1 of the opening 130H of the mold insulating layer 130. A passivation layer 142 and the first vertical extension portion 140V1 of the channel layer 140 may be arranged between the first part 144_1 of the gate insulating layer 144 and the mold insulating layer 130. The passivation layer 142 and the first vertical extension portion 140V1 of the channel layer 140 may not be provided between the second part 144_2 of the gate insulating layer 144 and the mold insulating layer 130.

The first part 144_1 of the gate insulating layer 144 may function as a gate insulating layer of the cell transistor CTR together with the passivation layer 142.

The word line WL may be arranged on the gate insulating layer 144. The word line WL may be arranged to face a sidewall of the first vertical extension portion 140V1 and a sidewall of the second vertical extension portion 140V2 of each of the plurality of channel layers 140. In some embodiments, the word line WL may include or be formed of Ti, TiN, Ta, TaN, Mo, Ru, W, WN, TiSiN, WSiN, polysilicon, or a combination thereof.

An insulating liner 152 may be arranged on the sidewalls of two word lines WL spaced apart from each other in the opening 130H, and a buried insulating layer 154 may be arranged to fill the space between two word lines WL spaced apart from each other on the insulating liner 152. The insulating liner 152 may be conformally arranged on opposite sidewalls of two word lines WL (i.e., a first word line WL1 and a second word line WL2), and may have an upper surface arranged on the same plane as the word lines WL. For example, the insulating liner 152 may include silicon nitride, and the buried insulating layer 154 may include silicon oxide.

An upper insulating layer 156 may be arranged on the word line WL and the buried insulating layer 154 in the opening 130H. The upper surface of the upper insulating layer 156 may be arranged at the same level as the mold insulating layer 130.

A plurality of landing pads LP may be arranged on upper surfaces of the plurality of channel layers 140. For example, a landing pad LP in contact with an upper surface of the channel layer 140 may be arranged on the upper insulating layer 156. A landing pad insulating layer 158 surrounding the periphery of the landing pad LP may be arranged on the mold insulating layer 130 and the upper insulating layer 156.

As illustrated in FIG. 5, in some embodiments, the landing pad LP may have a T-shaped vertical cross-section. The landing pad LP may include an upper part LPU and a lower part LPL. The upper part LPU of the landing pad LP may refer to a part of the landing pad LP arranged at a higher level than the upper surface of the mold insulating layer 130, and the lower part LPL of the landing pad LP may refer to a part of the landing pad LP arranged between the mold insulating layer 130 and the upper insulating layer 156. In some embodiments, the landing pad LP may include or be formed of Ti, TiN, Ta, TaN, W, WN, TiSiN, WSiN, polysilicon, or a combination thereof.

The bottom surface of the lower part LPL of the landing pad LP may be in contact with the upper surface of the channel layer 140, and both sidewalls of the lower part LPL of the landing pad LP may be aligned with both sidewalls of the channel layer 140. The bottom surface of the upper part LPU of the landing pad LP may be arranged at a higher level than the upper surface of the word line WL, and a part of the sidewall of the lower part LPL of the landing pad LP may be covered by the passivation layer 142. The upper surface of the passivation layer 142 may be arranged at the same level as the upper surface of the first part 144_1 of the gate insulating layer 144, and the upper surface of the passivation layer 142 and the upper surface of the first part 144_1 of the gate insulating layer 144 may be covered by the bottom surface of the upper part LPU of the landing pad LP. For example, the upper surface of the passivation layer 142 and the upper surface of the first part 144_1 of the gate insulating layer 144 may overlap the bottom surface of the upper part LPU of the landing pad LP in a vertical direction.

An etching stop layer 162 may be arranged on the landing pad LP and the landing pad insulating layer 158. A capacitor structure CAP may be arranged on the etching stop layer 162, and an interlayer insulating layer 172 may be arranged on the capacitor structure CAP. In some embodiments, the capacitor structure CAP may include a lower electrode (not illustrated), a capacitor dielectric layer (not illustrated), and an upper electrode (not illustrated). However, other types of memory storage components may be arranged in place of the capacitor structure CAP. For example, the memory storage component may include a variable resistance memory component, a phase change memory component, a magnetic memory component, and the like.

A contact plug MCT that penetrates the mold insulating layer 130 and is electrically connected to the lower wiring line ML1 and an intermediate wiring line ML2. The intermediate wiring line ML2 may be arranged on the mold insulating layer 130 and placed at the same vertical level as the landing pad LP. An upper wiring line ML3 may be electrically connected to the intermediate wiring line ML2 via the contact plug MCT penetrating an interlayer insulating layer 172. The contact plug MCT, the intermediate wiring line ML2, and the upper wiring line ML3 may be arranged in the peripheral circuit area PCA.

In general, the channel layer 140 including the oxide semiconductor material may have a low leakage current, which has an advantage in scale-down of the semiconductor device, and may have a relatively large change in electrical characteristics depending on the composition of the oxide semiconductor material. After a process of forming the channel layer 140, when impurities are introduced into the channel layer 140 or a local composition change of the channel layer 140 occurs, during a manufacturing process of the semiconductor device, there may be a problem that an electrical characteristic change of the semiconductor device is caused.

According to some embodiments, the passivation layer 142 may be arranged on the upper surface and inner wall of the channel layer 140, and the surface of the channel layer 140 may be prevented from being damaged in the process for node separation of the channel layer 140. The semiconductor device 100 may have a reduced surface trap state, thereby exhibiting excellent electrical characteristics.

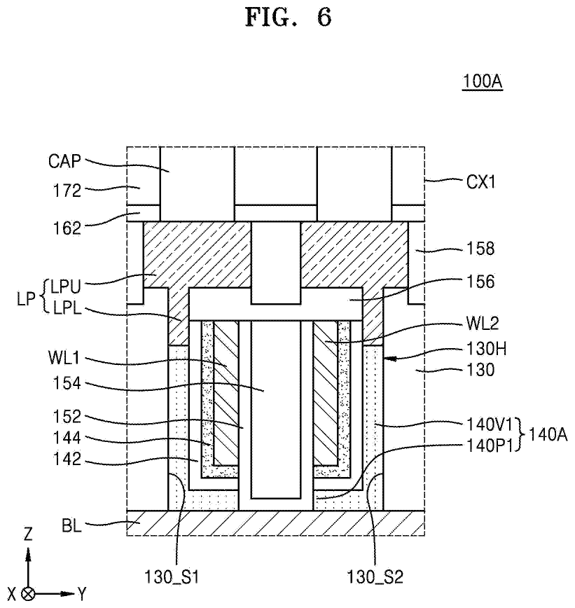

FIG. 6 is a cross-sectional view illustrating a semiconductor device according to example embodiments.

Referring to FIG. 6, a semiconductor device 100A may include a channel layer 140A having an L-shaped vertical cross-section. For example, the channel layer 140A may include a vertical extension portion 140V1 arranged on the first sidewall 130_S1 of the opening 130H of the mold insulating layer 130, and a horizontal extension portion 140P1 extending horizontally from the lower end of the vertical extension portion 140V1. In addition, the channel layer 140A may include a vertical extension portion 140V1 arranged on the second sidewall 130_S2 of the opening 130H of the mold insulating layer 130, and a horizontal extension portion 140P1 extending horizontally from the lower end of the vertical extension portion 140V1. An insulating liner 152 and a buried insulating layer 154 may be arranged between the channel layer 140A arranged on the first sidewall 130_S1 of the opening 130H and the channel layer 140A arranged on the second sidewall 130_S2 of the opening 130H, and the insulating liner 152 may contact the upper surface of the bit line BL.

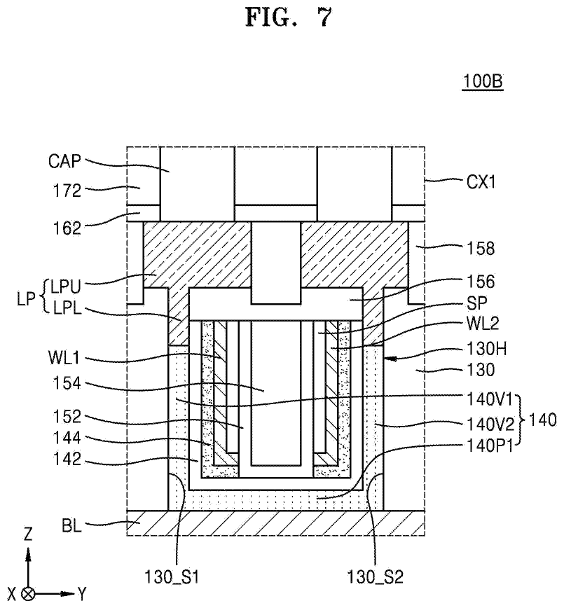

FIG. 7 is a cross-sectional view illustrating a semiconductor device according to example embodiments.

Referring to FIG. 7, a semiconductor device 100B may include first and second word lines WL1 and WL2. The first word line WL1 may have an L-shaped vertical cross-section, and the second word line WL2 may have a mirror symmetrical shape with the first word line WL1. The first word line WL1 may include a vertical extension portion arranged on the first sidewall 130_S1 of the opening 130H of the mold insulating layer 130, and a horizontal extension portion extending in a horizontal direction from a lower end of the vertical extension portion of the first word line WL1, and the second word line WL2 may include a vertical extension portion arranged on the second sidewall 130_S2 of the opening 130H of the mold insulating layer 130 and a horizontal extension portion extending in a horizontal direction from a lower end of the vertical extension portion of the second word line WL2.

Spacers SP may be arranged between the first word line WL1 and the insulating liner 152 and between the second word line WL2 and the insulating liner 152, and each of the spacers SP may be arranged on the horizontal extension portion of each of the first word line WL1 and the second word line WL2.

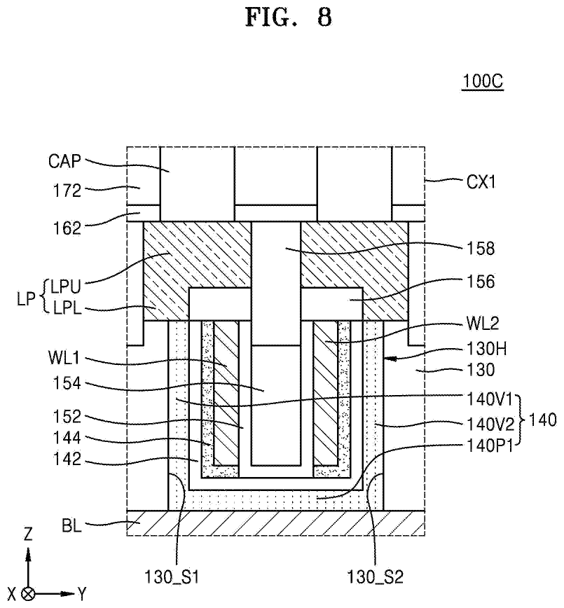

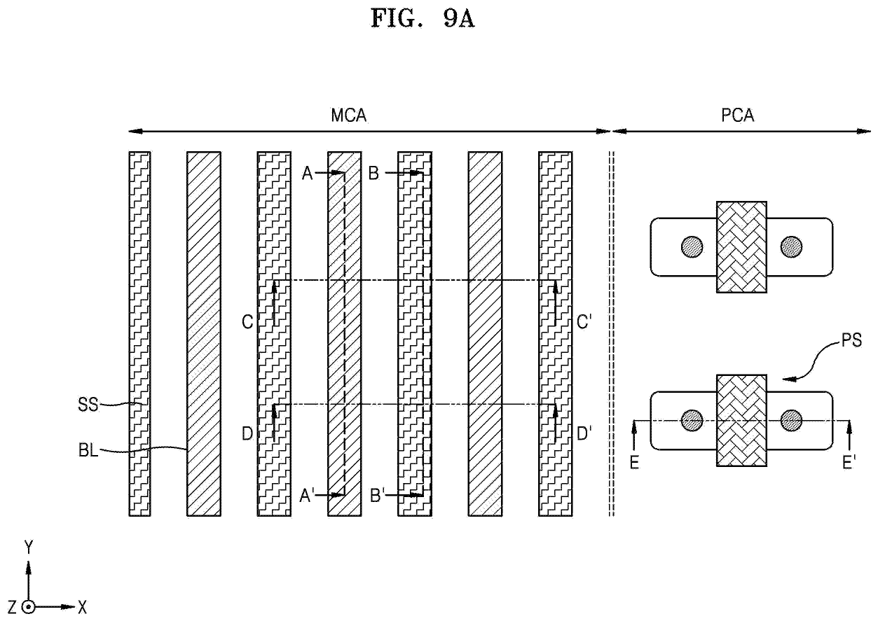

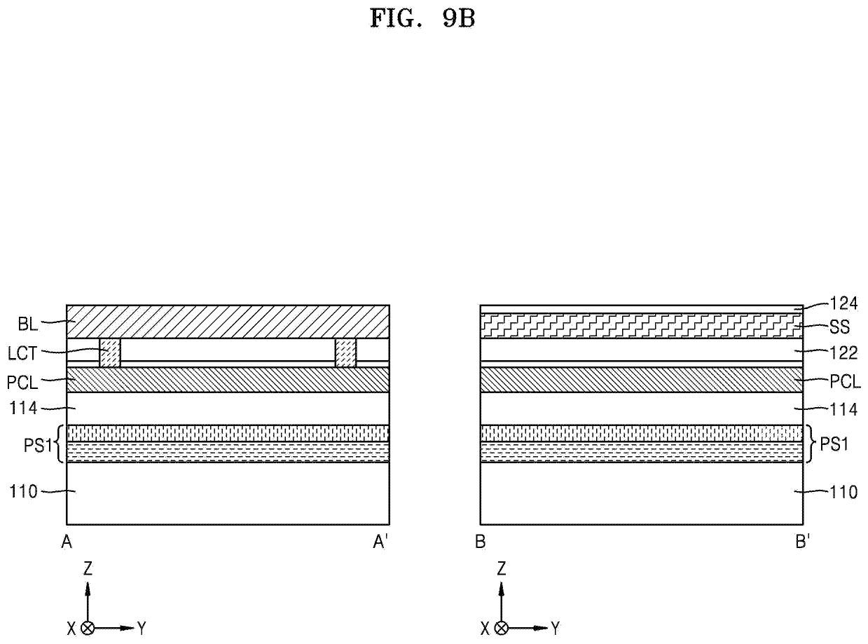

FIG. 8 is a cross-sectional view illustrating a semiconductor device according to example embodiments.

Referring to FIG. 8, a semiconductor device 100C may include a landing pad LP having an inverted L-shaped vertical cross-section. The landing pad LP includes an upper part LPU and a lower part LPL, and the bottom surface of the lower part LPL may contact the upper surface of the channel layer 140 and the upper surface of the mold insulating layer 130. In addition, a width of the lower part LPL in the second horizontal direction Y may be greater than a width of the channel layer 140 in the second horizontal direction Y.

According to some embodiments, before the landing pad LP is formed, the upper side of the mold insulating layer 130 may be removed by a recess process so that the upper surface of the mold insulating layer 130 is arranged at a lower level than the upper surface of the gate insulating layer 144. Accordingly, the upper surfaces of the mold insulating layer 130 and the channel layer 140 may be arranged on the same plane. In addition, the bottom surface of the landing pad LP is arranged at a vertical level higher than the top surface of the word line WL, thereby preventing horizontal overlap between the landing pad LP and the word line WL.

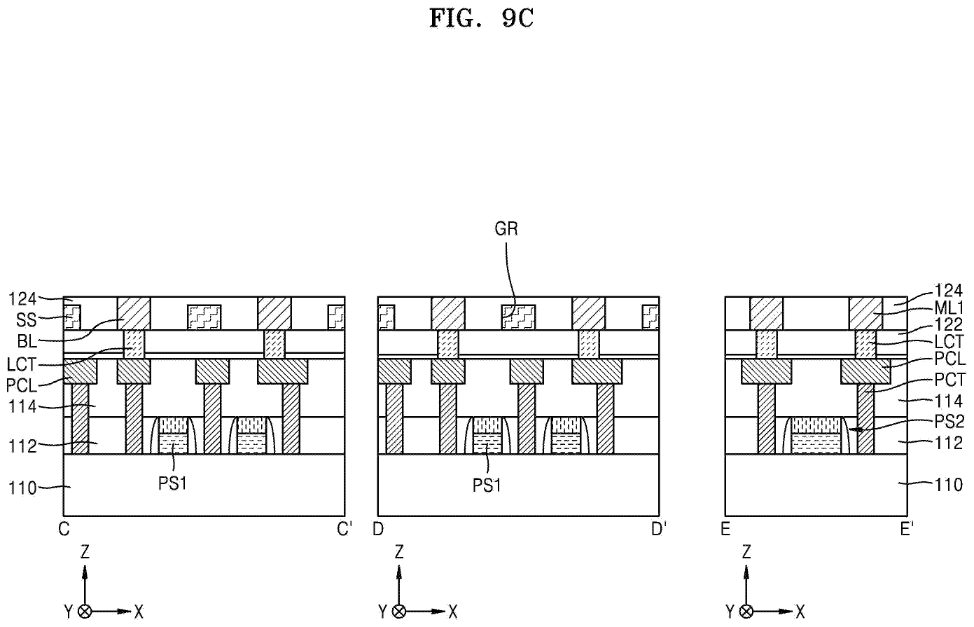

FIGS. 9A to 15A, 9B to 15B, and 9C to 15C are schematic diagrams illustrating a method of manufacturing a semiconductor device 100 according to embodiments. FIGS. 9A, 10A, 11A, 12A, 13A, 14A, and 15A are plan views of semiconductor devices schematically shown according to process order, FIGS. 9B, 10B, 11B, 12B, 13B, 14B, and 15B are cross-sectional views taken along lines A-A′ and B-B′ of FIG. 9A, and FIGS. 9C, 10C, 11C, 12C, 13C, 14C, and 15C are cross-sectional views taken along lines C-C′, D-D′, and E-E′ of FIG. 9A.

Referring to FIGS. 9A to 9C, a peripheral circuit structure PS is formed on a substrate 110. The peripheral circuit structure PS may include core circuits PS1 and peripheral circuits PS2. For example, the core circuits PS1 may be formed on a cell array area MCA, and the peripheral circuits PS2 may be formed on a peripheral circuit area PCA. In addition, a peripheral circuit wiring PCL and a peripheral circuit contact PCT electrically connected to the peripheral circuit structure PS, and a lower insulating layer 112 and a peripheral circuit insulating layer 114 covering the peripheral circuit structure PS may be formed.

Thereafter, a plurality of bit lines BL may be formed on the peripheral circuit insulating layer 114. For example, a first insulating layer 122 may be formed on the peripheral circuit insulating layer 114, and a line contact plug LCT may be formed through the first insulating layer 122 to be electrically connected to the peripheral circuit wiring PCL. Thereafter, a conductive layer (not illustrated) may be formed on the line contact plug LCT and the first insulating layer 122, and the conductive layer may be patterned to form a plurality of bit lines BL.

Thereafter, a second insulating layer 124 covering the bit lines BL may be formed. The second insulating layer 124 may be formed to cover an upper surface and a side surface of each of the bit lines BL and define gap regions GR. Thereafter, a conductive material such as tungsten, aluminum, or copper may be filled in the gap regions GR to form shield structures SS. Thereafter, a capping insulating layer (not shown) may be further formed on the upper surface of each of the shield structures SS.

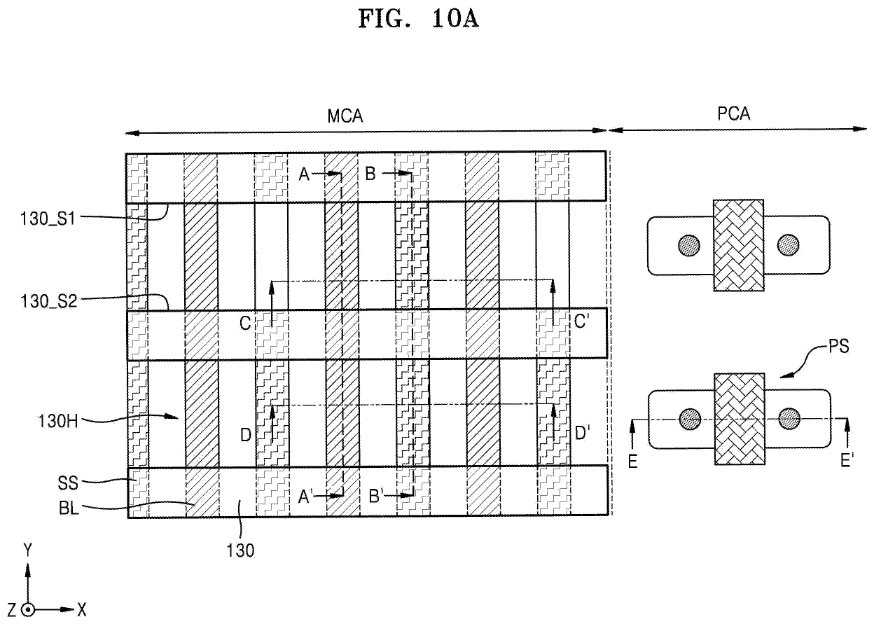

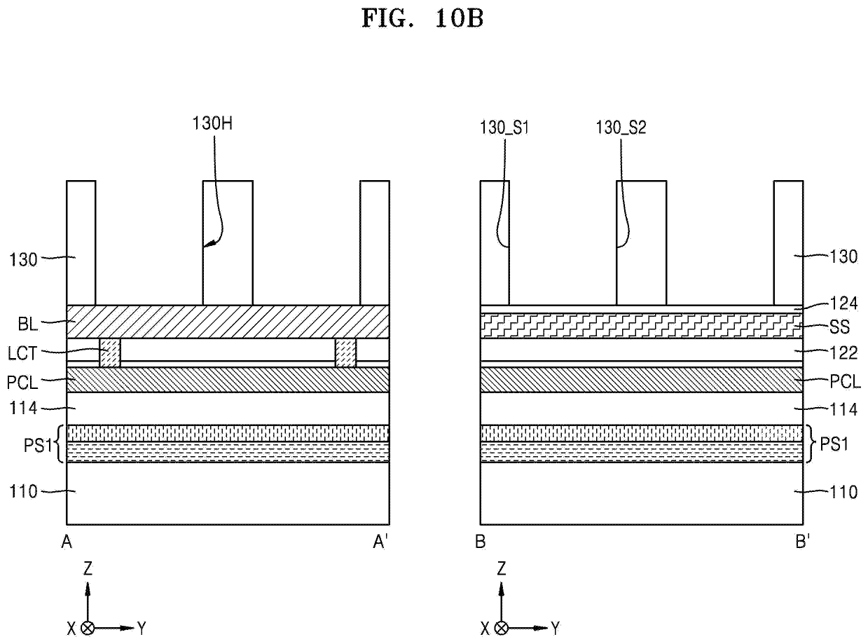

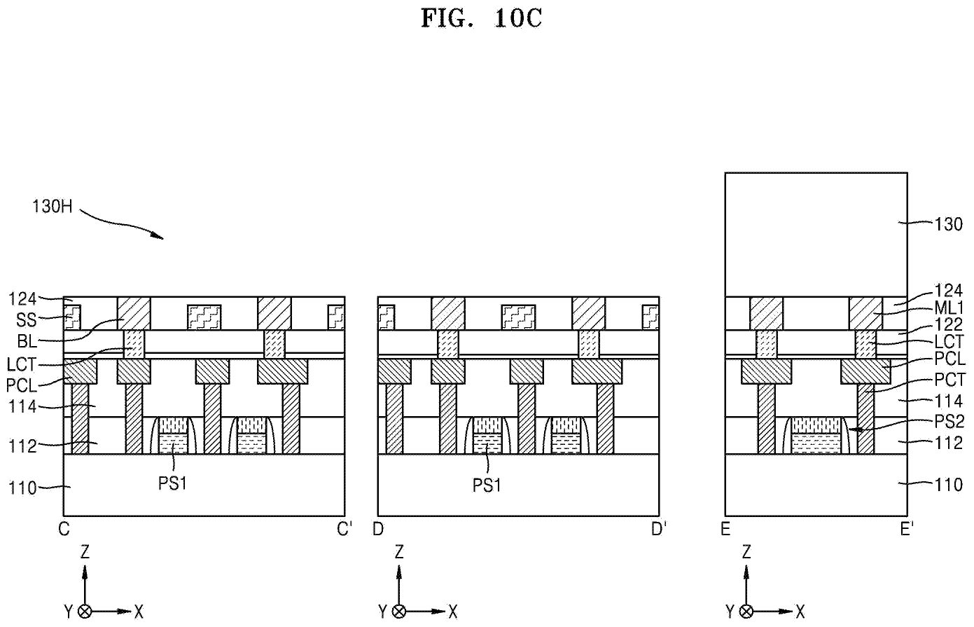

Referring to FIGS. 10A to 10C, a mold insulating layer 130 is formed on a bit line BL and a second insulating layer 124. The mold insulating layer 130 may include a plurality of openings 130H extending to the second horizontal direction Y, and an upper surface of each of the plurality of bit lines BL may be exposed at a bottom part of each of the plurality of openings 130H. Each of the plurality of openings 130H may include a first sidewall 130_S1 and a second sidewall 130_S2 opposite to each other and extending in the first horizontal direction X.

In some embodiments, the mold insulating layer 130 may be formed to have a relatively large height in the vertical direction Z by using at least one of silicon oxide, silicon nitride, silicon oxynitride, and a low-k dielectric material.

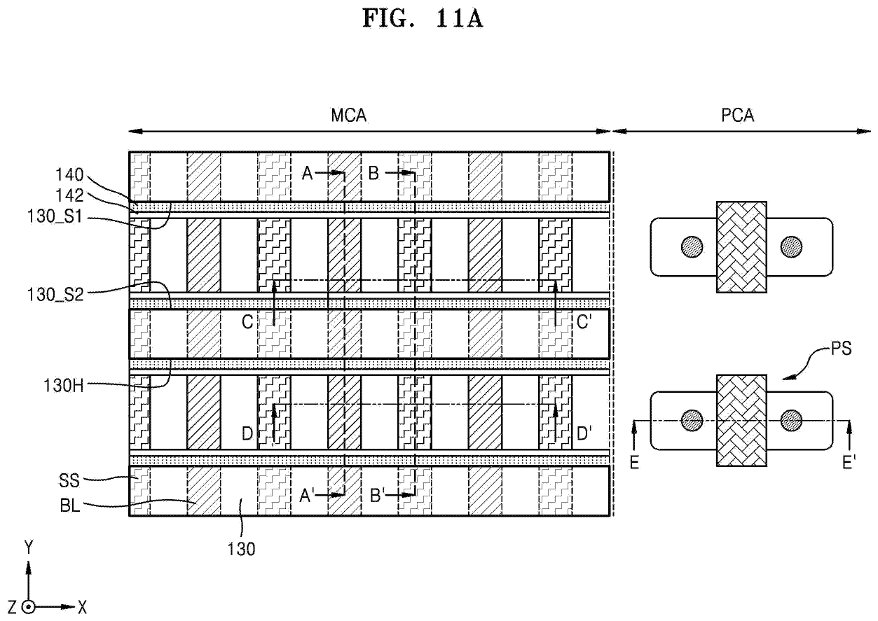

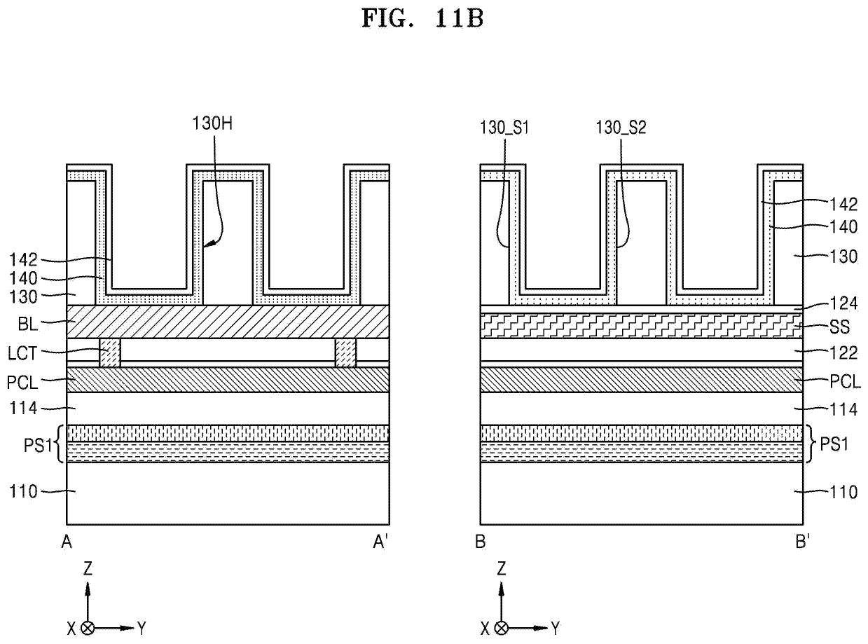

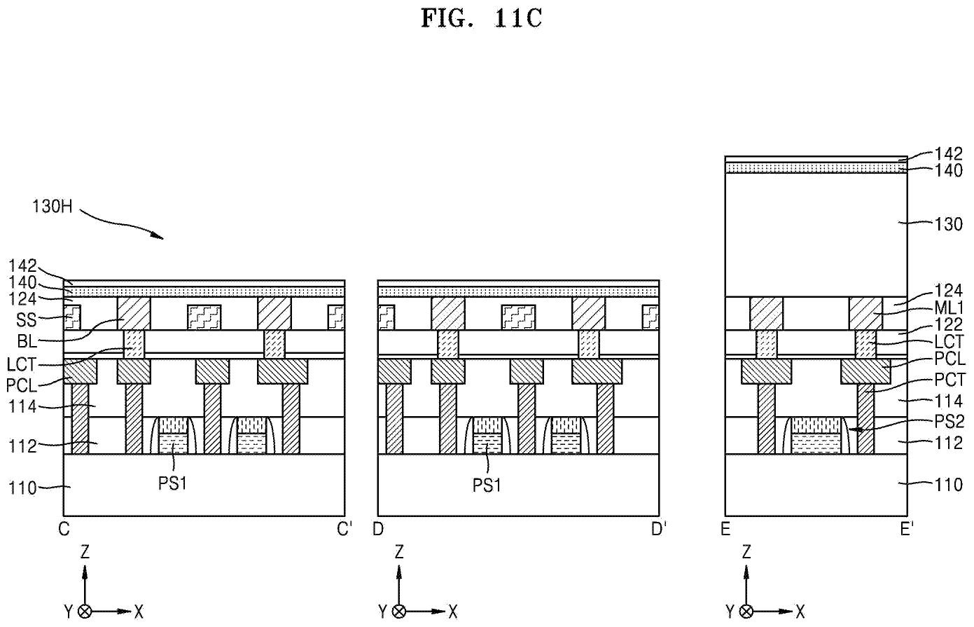

Referring to FIGS. 11A to 11C, the channel layer 140 may be formed on the mold insulating layer 130 to conformally cover the inner wall of each of the openings 130H.

In some embodiments, the channel layer 140 may be formed by using an oxide semiconductor material. For example, the channel layer 140 may include or be formed of at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), and zirconium zinc tin oxide (ZrₓZn_{y}Sn_{z}O). In some embodiments, the channel layer 140 may be formed by using at least one of a chemical vapor deposition (CVD) process, a low-pressure CVD process, a plasma-enhanced CVD process, a metal organic CVD (MOCVD) process, and an atomic layer deposition process. In some embodiments, the channel layer 140 may be formed to have a thickness of 1 to 50 nm, but is not limited thereto.

In some embodiments, an ion implantation process may be performed to dope impurities in a part of the channel layer 140 arranged at the bottom of the opening 130H of the mold insulating layer 130, thereby forming an impurity region (not shown) functioning as a source/drain region in a part of the channel layer 140 arranged adjacent to the bit line BL.

Thereafter, a passivation layer 142 may be formed on the channel layer 140. The passivation layer 142 may be formed to cover the entire exposed surface of the channel layer 140 and may be conformally arranged on the inner wall of the opening 130H of the mold insulating layer 130. In some embodiments, the passivation layer 142 may be formed to have a thickness of 1 to 50 nm, but is not limited thereto.

In some embodiments, the passivation layer 142 may be formed by at least one of a CVD process, a low pressure CVD process, a plasma enhanced CVD process, a MOCVD process, and an atomic layer deposition process. The passivation layer 142 may include or be formed of at least one of hafnium oxide, silicon oxide, aluminum oxide, zirconium oxide, lanthanum oxide, magnesium oxide, boron oxide, titanium oxide, aluminum nitride, aluminum oxynitride, silicon nitride, and silicon oxynitride.

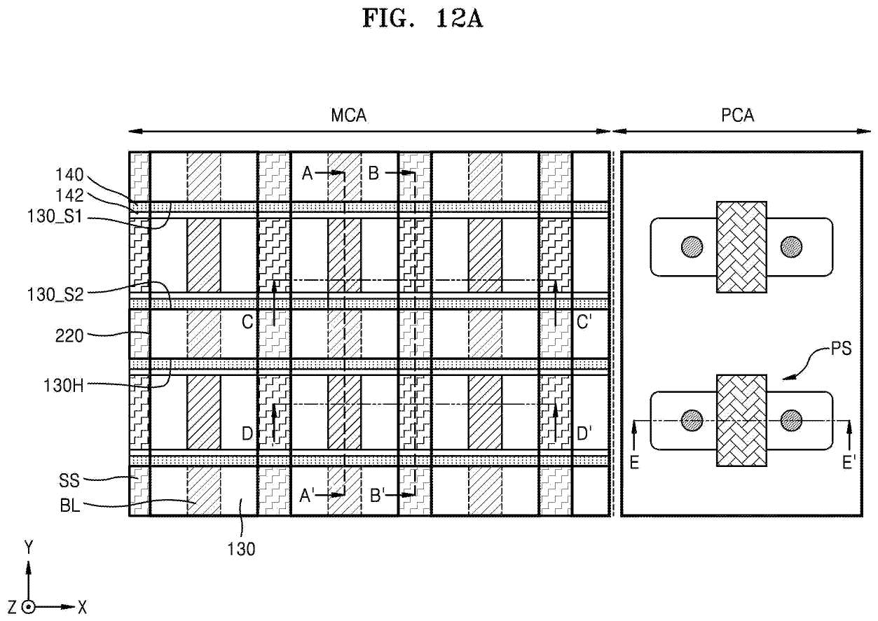

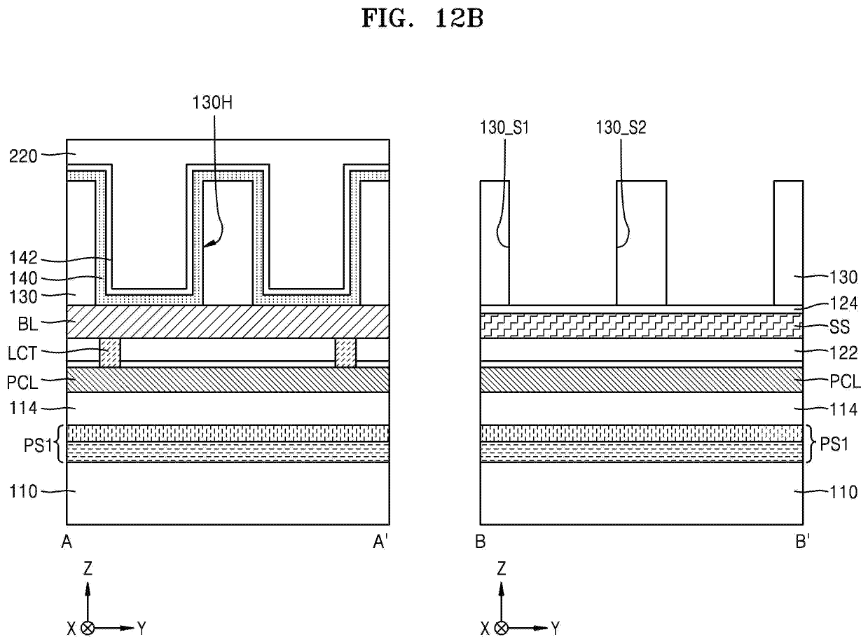

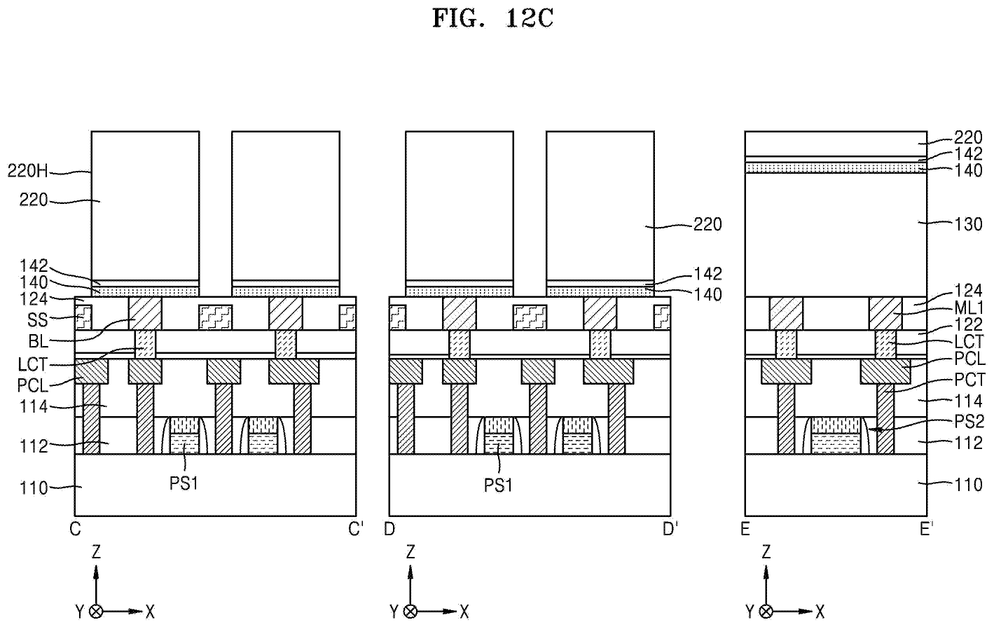

Referring to FIGS. 12A to 12C, a buried mask layer 220 may be formed on a passivation layer 142. In some embodiments, the buried mask layer 220 may be formed to be thick enough to fill the inside of the opening 130H of the mold insulating layer 130 and may have an opening 220H extending in the second horizontal direction Y, thereby having a line shape extending in the second horizontal direction Y.

In some embodiments, the buried mask layer 220 may include at least one of a spin-on hard mask (SOH), a spin-on dielectric (SOD), and an amorphous carbon layer (ACL).

Thereafter, the buried mask layer 220 may be used as an etching mask to remove a part of a passivation layer 142 and a part of a channel layer 140, which are exposed to the bottom of an opening 220H of the buried mask layer 220.

In some embodiments, after a part of the channel layer 140 is removed, the channel layer 140 may remain so as to extend in the second horizontal direction Y on the inner wall of the opening 130H of the mold insulating layer 130 and the upper surface of the mold insulating layer 130. In addition, the channel layer 140 arranged on one bit line BL may be arranged to be spaced apart from the channel layer 140 arranged on another bit line BL adjacent thereto. A process for removing a part of the channel layer 140 may be referred to as a node separation process of the channel layer 140.

Meanwhile, in the node separation process of the channel layer 140, the passivation layer 142 covers the entire surface of the channel layer 140 and is between the channel layer 140 and the buried mask layer 220, thereby preventing surface damage of the channel layer 140. In addition, in the node separation process of the channel layer 140, a part of the passivation layer 142 not covered by the buried mask layer 220 may also be removed, and a part of the passivation layer 142 covered by the buried mask layer 220 may remain on the channel layer 140 to have the same pattern shape as the channel layer 140.

A plurality of passivation layers 142 may be arranged on the inner wall of the opening 130H of the mold insulating layer 130 to be spaced apart from each other in the first horizontal direction X, and the plurality of passivation layers 142 may be arranged to vertically overlap the plurality of channel layers 140. The sidewalls 130_S1 and 130_S2 of the opening 130H of the mold insulating layer 130 may be exposed between two adjacent passivation layers 142 in the first horizontal direction X.

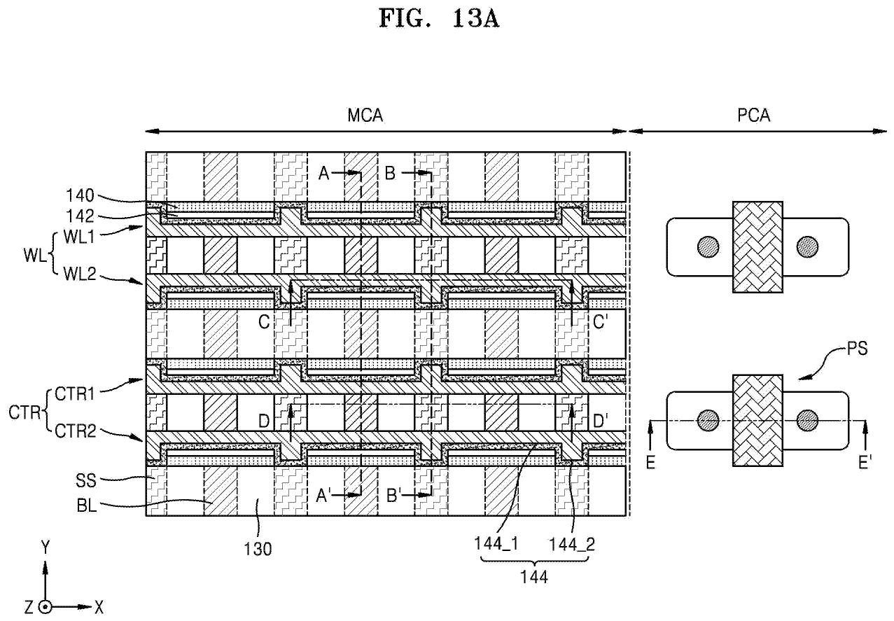

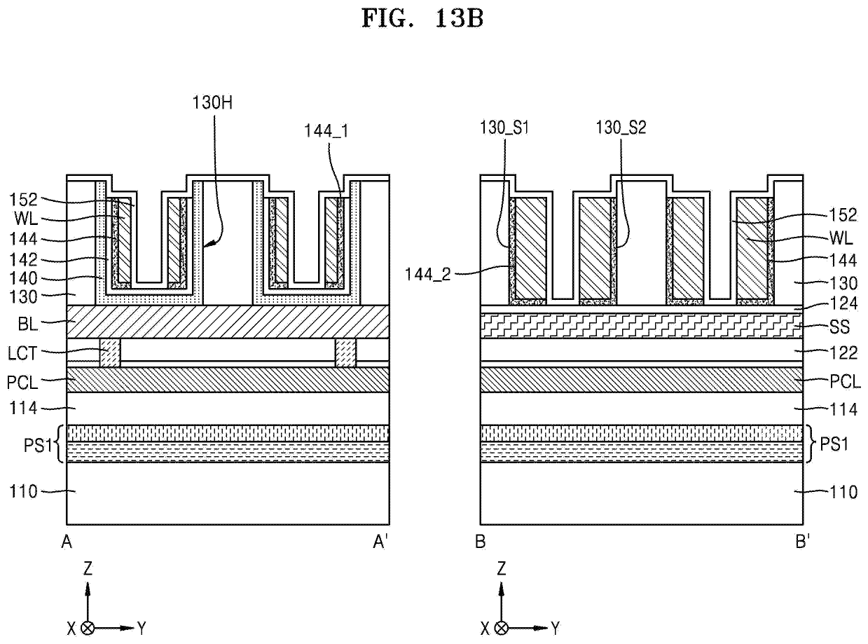

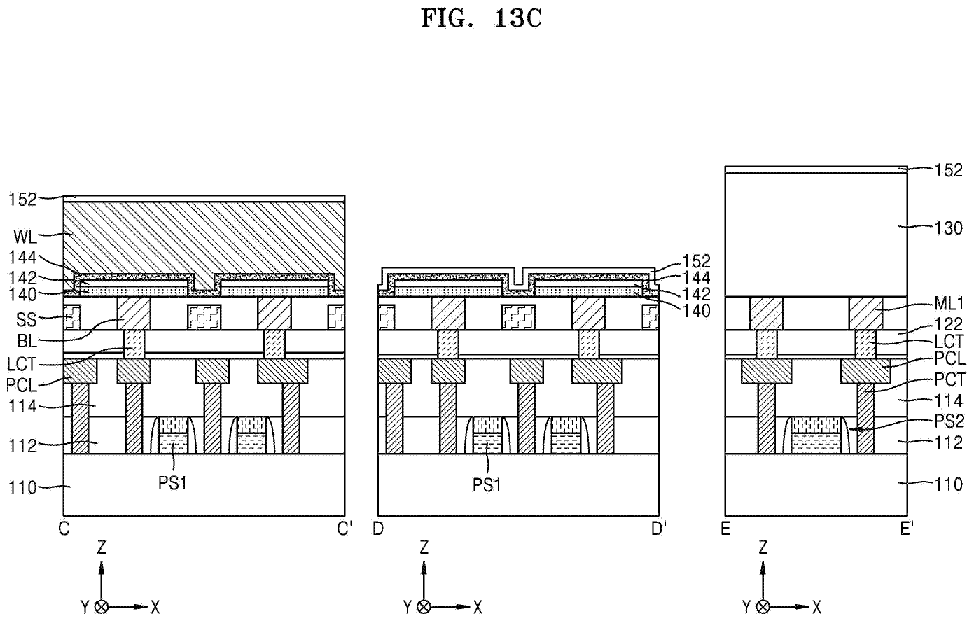

Referring to FIGS. 13A to 13C, the buried mask layer 220 (see FIG. 13B) may be removed.

In some embodiments, the process for removing the buried mask layer 220 may be a wet etching process or a wet cleaning process. In the process of removing the buried mask layer 220, the upper surface of the channel layer 140 may be covered by the passivation layer 142 so as not to be exposed to the etchant or cleaning solution, and surface damage of the channel layer 140 may be prevented.

Thereafter, the gate insulating layer 144 may be conformally formed on the inner wall of the opening 130H of the mold insulating layer 130. The gate insulating layer 144 may include a first part 144_1 arranged on the passivation layer 142 and a second part 144_2 arranged on the mold insulating layer 130. For example, the first part 144_1 of the gate insulating layer 144 does not contact the mold insulating layer 130, and the passivation layer 142 and the channel layer 140 may be between the first part 144_1 of the gate insulating layer 144 and the mold insulating layer 130. In addition, the second part 144_2 of the gate insulating layer 144 may contact the mold insulating layer 130 on the sidewalls 130_S1 and 130_S2 of the opening 130H and extend from the sidewalls 130_S1 and 130_S2 of the opening 130H to the upper surface of the mold insulating layer 130.

In some embodiments, the gate insulating layer 144 may be formed of at least one selected from a high-k dielectric material and a ferroelectric material having a dielectric constant higher than that of silicon oxide. In some embodiments, the gate insulating layer 144 may be formed of at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead titanate zirconate (PbZrTiO), tantalate strontium bismuth (SrTaBiO), bismuth iron oxide (BiFeO), strontium titanium oxide (SrTiO), yttrium oxide (YO), aluminum oxide (AlO), and lead scandium tantalum oxide (PbScTaO).

Then, a conductive layer (not shown) may be formed on the gate insulating layer 144, and an anisotropic etching process is performed on the conductive layer to remove a part of the conductive layer arranged on the bottom of the opening 130H, and to have a word line WL to be left on the sidewall of the opening 130H. In some embodiments, the word line WL may be formed by using Ti, TiN, Ta, TaN, Mo, Ru, W, WN, TiSiN, WSiN, polysilicon, or a combination thereof.

As illustrated in FIG. 13A, the word line WL may include a first word line WL1 and a second word line WL2, which are arranged to be spaced apart in each opening 130H. For example, the first word line WL1 may be arranged on the first sidewall 130_S1 of the opening 130H, and the second word line WL2 may be arranged on the second sidewall 130_S2 of the opening 130H. Accordingly, a part of the channel layer 140 arranged adjacent to the first sidewall 130_S1 and the first word line WL1 may form a first cell transistor CTR1, and a part of the channel layer 140 arranged adjacent to the second sidewall 130_S2 and the second word line WL2 may form a second cell transistor CTR2, in one opening 130H. In addition, as the first part 144_1 of the gate insulating layer 144 and the passivation layer 142 are between the word line WL and the channel layer 140, the first part 144_1 of the gate insulating layer 144, together with the passivation layer 142, may function as a gate insulating layer of the cell transistor CTR.

In some embodiments, in the process of leaving the word line WL on the sidewall of the opening 130H, a part of the gate insulating layer 144 arranged between the first word line WL1 and the second word line WL2 may also be removed from the bottom of the opening 130H, and the upper surface of the passivation layer 142 may be exposed between the first word line WL1 and the second word line WL2.

In some other embodiments, unlike illustrated in FIG. 13B, in the process of leaving the word line WL on the sidewall of the opening 130H, a part of the gate insulating layer 144, a part of the passivation layer 142, and a part of the channel layer 140, which are arranged between the first word line WL1 and the second word line WL2 may be further removed, and the channel layer 140 may be separated into a part arranged on the first sidewall 130_S1 of the opening 130H and a part arranged on the second sidewall 130_S2 of the opening 130H. In this case, the semiconductor device 100A described with reference to FIG. 6 may be manufactured.

In some embodiments, in the process of leaving the word line WL on the sidewall of the opening 130H, parts of the upper sides of the passivation layer 142 and the gate insulating layer 144 may be removed, and the upper surfaces of the passivation layer 142 and the gate insulating layer 144 may be arranged at the same vertical level as the upper surface of the word line WL. In addition, in the process of leaving the word line WL, the upper side of the channel layer 140 may not be removed, and the upper surface of the channel layer 140 may be arranged at the same level as the upper surface of the mold insulating layer 130. However, the technical idea of this inventive concept is not limited thereto, and unlike illustrated in FIG. 13B, the upper surfaces of the passivation layer 142 and the gate insulating layer 144 may be arranged at a higher level than the word line WL, and may be arranged at the same vertical level as the upper surfaces of the channel layer 140 and the mold insulating layer 130.

Thereafter, an insulating liner 152 covering the surface of the word line WL may be formed on the inner wall of the opening 130H. The insulating liner 152 may be conformally arranged on the upper surface of the channel layer 140 and the upper surface of the mold insulating layer 130. In some embodiments, the insulating liner 152 may include silicon nitride.

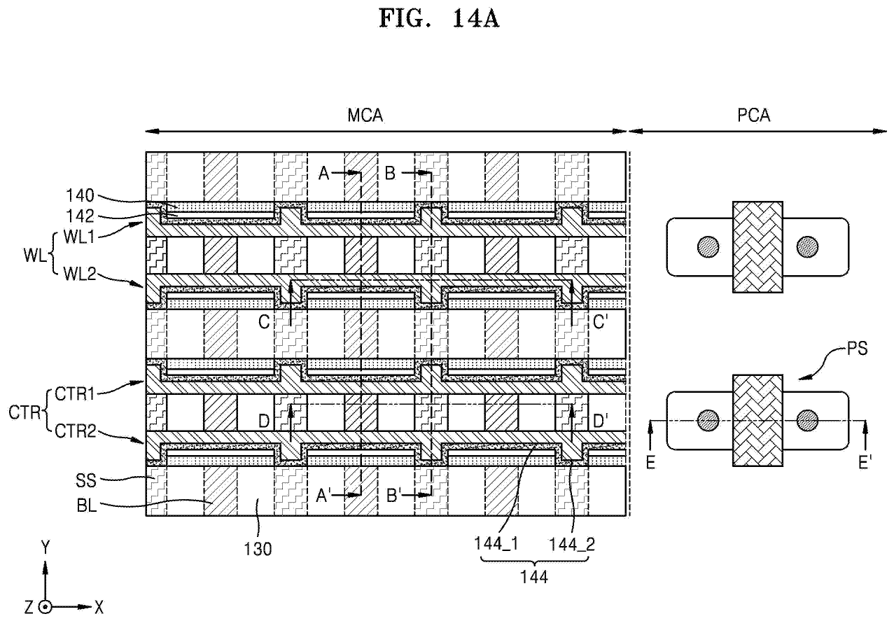

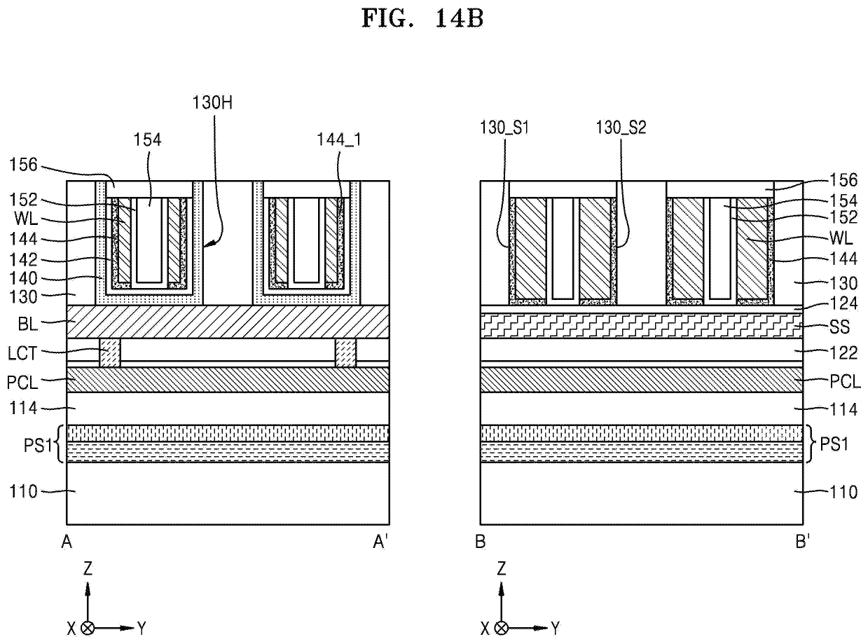

Referring to FIGS. 14A to 14C, a buried insulating layer 154 filling the inside of the opening 130H may be formed on the insulating liner 152. In some embodiments, the buried insulating layer 154 may be formed using silicon oxide.

In some embodiments, an etch-back process may be performed on the upper side of the buried insulating layer 154 to remove the insulating liner 152 on the upper surface of the word line WL and expose the upper surface of the word line WL again. As a result of the etch-back process, top surfaces of the buried insulating layer 154, the insulating liner 152, and the word line WL may be arranged at the same level.

Then, an insulating layer (not shown) filling the inside of the opening 130H may be formed on the buried insulating layer 154, the insulating liner 152, and the word line WL, and an upper surface of the insulating layer may be planarized until the upper surface of the mold insulating layer 130 is exposed to form an upper insulating layer 156 inside the opening 130H. In some embodiments, the upper insulating layer 156 may be formed using silicon nitride.

Thereafter, a contact plug MCT that is electrically connected to the lower wiring line ML1 through the mold insulating layer 130 in the peripheral circuit area PCA may be formed.

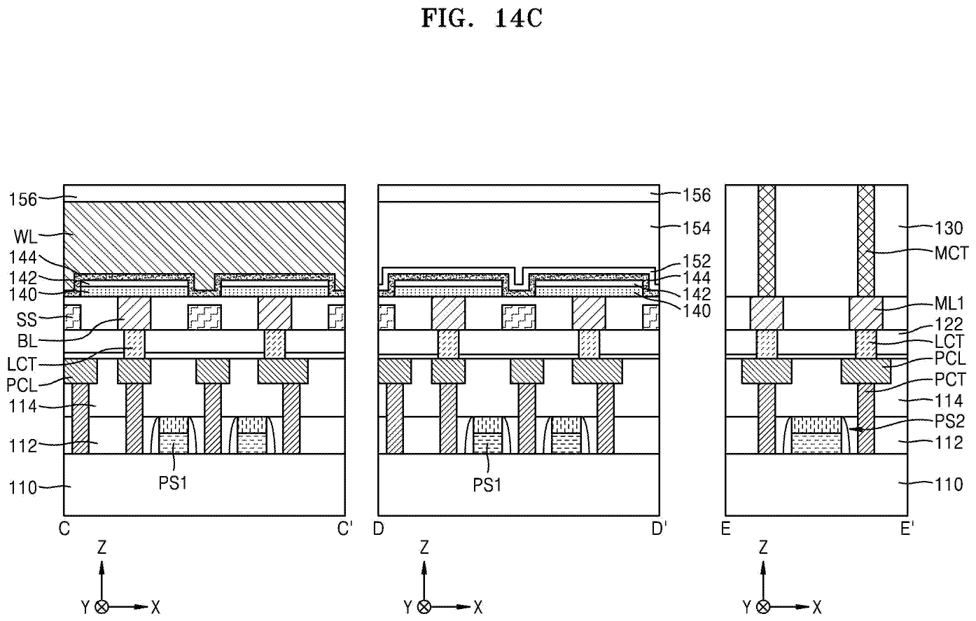

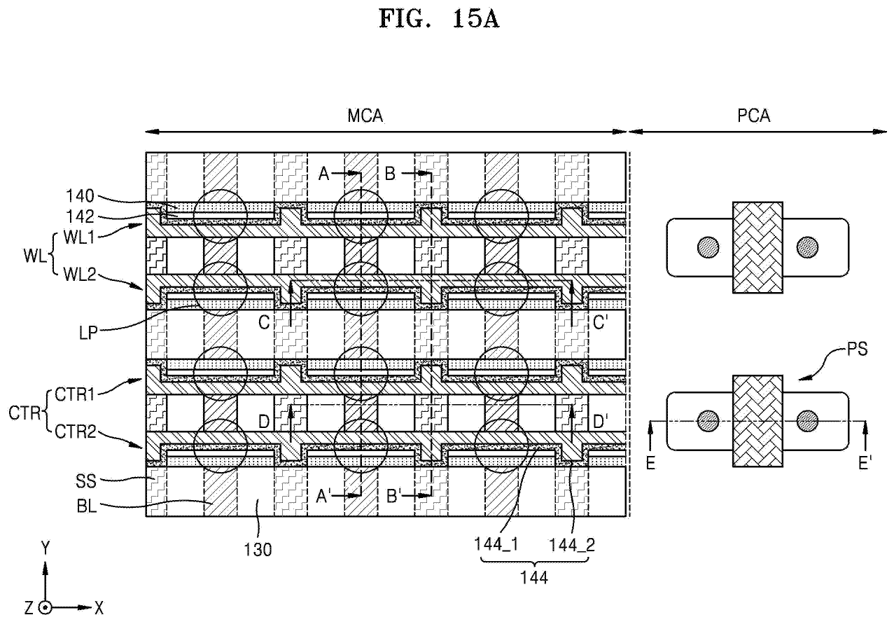

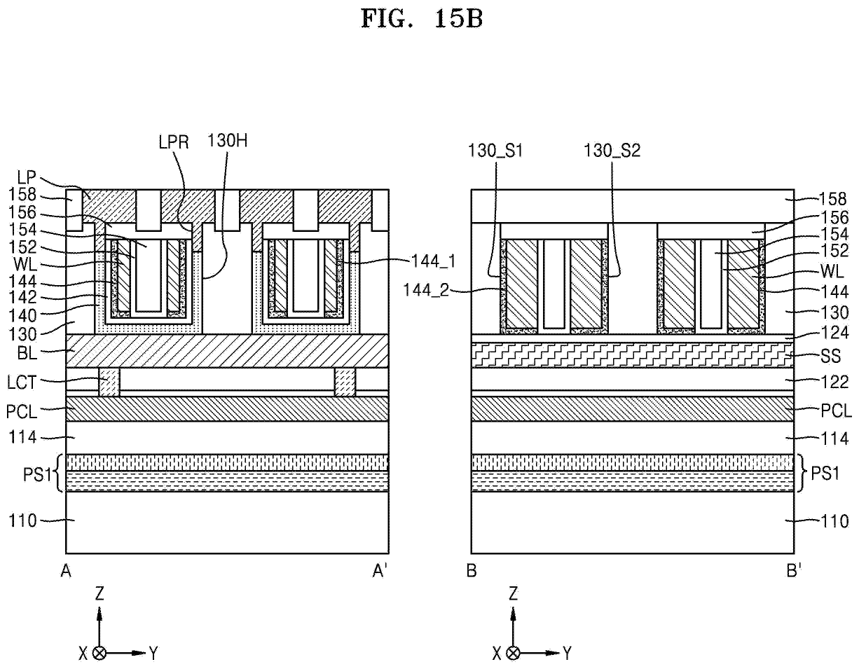

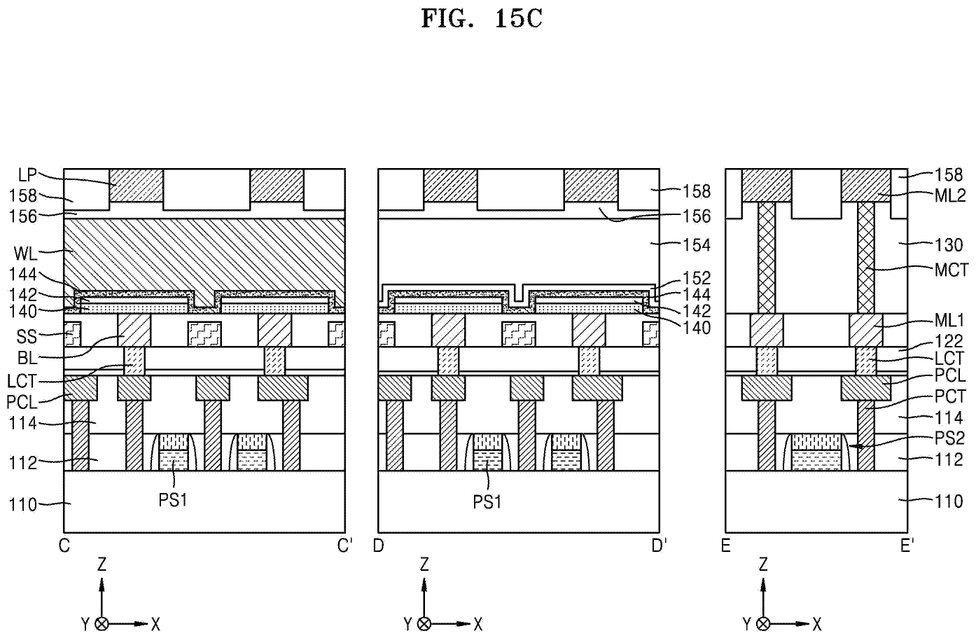

Referring to FIGS. 15A to 15C, a landing pad conductive layer (not illustrated) may be formed on the mold insulating layer 130 and the upper insulating layer 156, a mask pattern (not illustrated) may be formed on the landing pad conductive layer, and a part of the landing pad conductive layer may be removed using the mask pattern, to form a landing pad LP. Thereafter, a landing pad insulating layer 158 may be formed using an insulating material in a region from which the landing pad conductive layer is removed.

In some embodiments, a part of the upper side of the channel layer 140 may be removed by an etch-back process to form a landing pad recess LPR recessed in a vertical direction from the upper surface of the mold insulating layer 130, and the landing pad conductive layer may be filled in the landing pad recess LPR to form a landing pad LP having a T-shaped vertical cross-section as illustrated in FIG. 15B.

In some other embodiments, the upper surface of the mold insulating layer 130 and the upper surface of the channel layer 140 may be arranged at a lower level than the upper insulating layer 156 by performing a recess process of removing a part of the upper side of the mold insulating layer 130 and a part of the upper side of the channel layer 140, and a landing pad conductive layer (not shown) may be formed on the mold insulating layer 130 and the upper insulating layer 156, to form a landing pad LP. In this case, the semiconductor device 100C described with reference to FIG. 8 may be manufactured.

Referring back to FIGS. 2 to 4, an etching stop layer 162 may be formed on the landing pad LP and the landing pad insulating layer 158. A capacitor structure CAP may be formed on the etching stop layer 162.

The semiconductor device 100 may be completed by performing the above-described processes.

According to embodiments, with the passivation layer 142 formed on the upper surface of the channel layer 140, processes may be performed so that the buried mask layer 220 may be formed to separate nodes of the channel layer 140, the channel layer 140 may be patterned using the buried mask layer, and then the buried mask layer 220 may be removed. Therefore, surface damage of the channel layer 140 may be prevented in the processes for node separation of the channel layer 140, and the semiconductor device 100 may have excellent electrical properties.

While the inventive concept has been particularly shown and described with reference to embodiments thereof, it will be understood that various changes in form and details may be made therein without departing from the spirit and scope of the following claims.

What is claimed is:

1. A semiconductor device comprising:
a plurality of bit lines arranged on a substrate and extending in a first horizontal direction;
a mold insulating layer arranged on the plurality of bit lines and including a plurality of openings extending in a second horizontal direction, respectively;
a plurality of channel layers respectively arranged on the plurality of bit lines and including a first vertical extension portion, in each opening of the mold insulating layer;
a plurality of passivation layers respectively arranged on each first vertical extension portion;
a gate insulating layer arranged to face each first vertical extension portion with each passivation layer therebetween; and
a plurality of word lines extending in the second horizontal direction on the gate insulating layer and including first word lines respectively arranged on a first sidewall of each opening of the mold insulating layer and second word lines respectively arranged on a second sidewall of each opening of the mold insulating layer.

2. The semiconductor device of claim 1, wherein each of the plurality of passivation layers includes at least one of hafnium oxide, silicon oxide, aluminum oxide, zirconium oxide, lanthanum oxide, magnesium oxide, boron oxide, titanium oxide, aluminum nitride, aluminum oxynitride, silicon nitride, and silicon oxynitride.

3. The semiconductor device of claim 1, wherein the gate insulating layer includes at least one of a high-k dielectric material and a ferroelectric material, and
wherein each of the plurality of channel layers includes at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), and zirconium zinc tin oxide (ZrₓZn_{y}Sn_{z}O).

4. The semiconductor device of claim 1, wherein, for each of the plurality of channel layers:
the channel layer includes a first sidewall and a second sidewall, which are opposite to each other,
the first sidewall of the channel layer is covered by the mold insulating layer, and
the second sidewall of the channel layer is covered by a part of the passivation layers.

5. The semiconductor device of claim 1, wherein each first vertical extension portion is arranged on the first sidewall of each opening of the mold insulating layer,
wherein each of the plurality of channel layers further includes:
a second vertical extension portion arranged on the second sidewall of each opening of the mold insulating layer, and
a horizontal extension portion arranged on a bottom surface of each opening of the mold insulating layer and arranged on each bit line,
wherein each first word line is arranged on a sidewall of each first vertical extension portion, and
wherein each second word line is arranged on a sidewall of each second vertical extension portion.

6. The semiconductor device of claim 5, wherein, for each of the plurality of channel layers:
the first vertical extension portion of the channel layer is arranged between a part of the passivation layers and the first sidewall of each opening of the mold insulating layer,
the second vertical extension portion of the channel layer is arranged between a part of the passivation layers and the second sidewall of each opening of the mold insulating layer, and
the parts of the passivation layers do not contact the mold insulating layer.

7. The semiconductor device of claim 5, wherein the gate insulating layer includes:
a first part arranged on a sidewall of each passivation layer and not in contact with the first sidewall of each opening of the mold insulating layer, and
a second part in contact with the first sidewall of each opening of the mold insulating layer, and
wherein the first vertical extension portion of each channel layer is arranged between the first part of the gate insulating layer and the mold insulating layer.

8. The semiconductor device of claim 7, wherein each passivation layer and each first vertical extension portion are not provided between the second part of the gate insulating layer and the mold insulating layer.

9. The semiconductor device of claim 7, further comprising:
a plurality of landing pads arranged on upper surfaces of the plurality of channel layers,
wherein at least a part of a lower side of a sidewall of each landing pad is covered by a part of the passivation layers.

10. The semiconductor device of claim 9, wherein, for each of the passivation layers:
an upper surface of the passivation layer is arranged on the same plane as an upper surface of the first part of the gate insulating layer, and
the upper surface of the passivation layer and the upper surface of the first part of the gate insulating layer overlap each landing pad in a vertical direction.

11. The semiconductor device of claim 1, further comprising:
a peripheral circuit arranged between the substrate and the plurality of bit lines and electrically connected to the plurality of bit lines; and
a shield structure extending in the first horizontal direction between the plurality of bit lines.

12. A semiconductor device comprising:
a plurality of bit lines arranged on a substrate and extending in a first horizontal direction;
a mold insulating layer arranged on the plurality of bit lines and including a plurality of openings extending in a second horizontal direction, respectively;
a plurality of channel layers respectively arranged on the plurality of bit lines, and including a vertical extension portion and a horizontal extension portion, in each opening of the mold insulating layer;
a plurality of passivation layers respectively arranged on each vertical extension portion and each horizontal extension portion, and including an oxide;
a gate insulating layer arranged to face each vertical extension portion and each horizontal extension portion with each passivation layer therebetween; and
a plurality of word lines extending in the second horizontal direction on the gate insulating layer.

13. The semiconductor device of claim 12, wherein:
each of the plurality of passivation layers includes at least one of hafnium oxide, silicon oxide, aluminum oxide, zirconium oxide, lanthanum oxide, magnesium oxide, boron oxide, titanium oxide, aluminum nitride, aluminum oxynitride, silicon nitride, and silicon oxynitride, and
the gate insulating layer includes at least one of a high-k dielectric material and a ferroelectric material.

14. The semiconductor device of claim 12, wherein, for each of the plurality of channel layers:
the channel layer includes a first sidewall and a second sidewall, which are opposite to each other,
the first sidewall of the channel layer is covered by the mold insulating layer, and
the second sidewall of the channel layer is covered by a part of the passivation layers.

15. The semiconductor device of claim 12, wherein the gate insulating layer includes:
a first part arranged on a sidewall of each passivation layer and not in contact with a sidewall of each of opening of the mold insulating layer, and
a second part in contact with the sidewall of each of opening of the mold insulating layer, and
wherein the vertical extension portion of each channel layer is arranged between the first part of the gate insulating layer and the mold insulating layer.

16. The semiconductor device of claim 15, wherein each passivation layer and each vertical extension portion are not provided between the second part of the gate insulating layer and the mold insulating layer.

17. The semiconductor device of claim 15, further comprising:
a plurality of landing pads arranged on upper surfaces of the plurality of channel layers,
wherein at least a part of a lower side of a sidewall of each landing pad is covered by a part of the passivation layers.

18. The semiconductor device of claim 17, wherein, for each of the passivation layers:
an upper surface of the passivation layer is arranged on the same plane as an upper surface of the second part of the gate insulating layer, and
the upper surface of the passivation layer and the upper surface of the second part of the gate insulating layer overlap each landing pad in a vertical direction.

19. A semiconductor device comprising:
a peripheral circuit arranged on a substrate;
a plurality of bit lines arranged on the peripheral circuit and extending in a first horizontal direction;
a shield structure extending in the first horizontal direction between the plurality of bit lines;
a mold insulating layer arranged on the plurality of bit lines and the shield structure and including a plurality of openings extending in a second horizontal direction, respectively;
a plurality of channel layers arranged on the plurality of bit lines, respectively, and including vertical and horizontal extension portions, in each opening of the mold insulating layer;
a plurality of passivation layers respectively arranged on each vertical extension portion and each horizontal extension portion, and including an oxide;
a gate insulating layer arranged to face each vertical extension portion and each horizontal extension portion with each passivation layer therebetween;
a plurality of word lines extending in the second horizontal direction on the gate insulating layer;
a landing pad formed on each channel layer; and
a capacitor structure arranged on the landing pad.

20. The semiconductor device of claim 19, wherein the gate insulating layer includes:
a first part arranged on a sidewall of each passivation layer and not in contact with a sidewall of each opening of the mold insulating layer, and
a second part in contact with the sidewall of each opening of the mold insulating layer, and
wherein the vertical extension portion of each channel layer is arranged between the first part of the gate insulating layer and the mold insulating layer.
